(19) United States
(12) Patent Application Publication
(10) Pub. No.: US 2023/0023610 A1
(43) Pub. Date: Jan. 26, 2023

(54) CERAMIC SUBSTRATE FOR POWER MODULE AND POWER MODULE COMPRISING SAME

(71) Applicant: AMOSENSE CO.,LTD, Cheonan-si, Chungcheongnam-do (KR)

(72) Inventor: Ji-Hyung LEE, Cheonan-si (KR)

(73) Assignee: AMOSENSE CO.,LTD, Cheonan-si, Chungcheongnam-do (KR)

(21) Appl. No.: 17/786,461

(22) PCT Filed: Dec. 14, 2020
(86) PCT No.: PCT/KR2020/018268

§ 371 Date: Jun. 16, 2022

(30) Foreign Application Priority Data
Dec. 16, 2019 (KR) 10-2019-0168176
Dec. 16, 2019 (KR) 10-2019-0168177

(51) Int. Cl. H01L 23/373; H01L 23/00; H05K 1/02; H05K 1/03

(52) U.S. Cl. CPC H01L 23/3735; H01L 24/32; H05K 1/0209; H05K 1/0306; H01L 2224/32225; H01L 2224/32245; H01L 2924/1033; H01L 2924/10272; H01L 2924/13055; H01L 2924/1203; H05K 2201/10166; H05K 2201/10174; H05K 2201/042

(57) ABSTRACT

A ceramic substrate according to the present invention includes: a ceramic base material; an electrode pattern formed on the ceramic base material; and at least one spacer arranged in any one of regions in the ceramic base material and the electrode pattern, in which a semiconductor chip is mounted.

### TECHNICAL FIELD

The present disclosure relates to a ceramic substrate for a power module capable of effectively dissipating heat generated from a semiconductor chip, and the power module including the same.

### BACKGROUND ART

Due to environmental problems and depletion of fossil energy, interest in and development of hybrid electric vehicles and electric vehicles is increasing. The eco-friendly vehicles are provided with a power conversion device such as an inverter or a converter to convert power supplied from a rechargeable battery or a fuel cell using hydrogen fuel into power for driving a motor.

The power conversion device includes a power module on which a power semiconductor chip for power conversion is mounted.

Typically, the power module is configured by mounting a semiconductor chip formed of an insulated gate bipolar transistor (IGBT) or a diode, or made of a material such as a gallium nitride (GaN) or a silicon carbide (SiC) on a ceramic substrate.

The semiconductor chip provided in the power module generates a lot of heat in the power converting process, and when the generated heat is not quickly dissipated, the characteristics of the semiconductor chip may be degraded and the semiconductor chip may not be stably operated, so that heat-dissipation means of various types of power modules are being proposed.

Recently, to improve the heat-dissipation performance of the power module, a double side cooling (DSC) power module in which a semiconductor chip is mounted between a pair of ceramic substrates to dissipate heat to both surfaces of the semiconductor chip is being proposed. The double side cooling power module has a structure in which an electrode pattern is formed on one surface of each of a pair of substrates and a semiconductor chip is mounted between the pair of electrode patterns facing each other, and may install a heat sink on each ceramic substrate, thereby improving the heat-dissipation effect compared to the conventional single side cooling type.

However, in the double side cooling power module, as a support structure installed to maintain a separation distance between ceramic substrates thermally expands due to heat emitted from the semiconductor chip, the distance between the ceramic substrates may not be constantly maintained, so that the semiconductor chip mounted between the ceramic substrates may be separated from the electrode pattern of the ceramic substrate.

To prevent the separation, a thermal interface material such as TIM may be interposed between the semiconductor chip and the electrode pattern, but silicon or polymer-based thermal interface materials do not have large heat capacity, and thus may not effectively transfer the high temperature of the semiconductor chip toward the ceramic substrate.

### SUMMARY OF INVENTION

### Technical Problem

The present disclosure has been made in efforts to solve the above problem, and an object of the present disclosure is to provide a ceramic substrate for a power module having an improved structure in which heat of a semiconductor chip may be effectively transferred toward the ceramic substrate, and the power module including the same.

### Solution to Problem

To achieve the object, according to one embodiment of the present disclosure, there is provided a ceramic substrate for a power module including a ceramic base material, at least one electrode pattern formed on the ceramic base material, and at least one spacer disposed on the ceramic base material or the electrode pattern, in which the spacer may have electrical conductivity and thermal conductivity, and may be made of a material having a lower coefficient of thermal expansion than that of the electrode pattern.

The spacer may be bonded to a semiconductor chip mounted on the electrode pattern.

The spacer may be mounted on the electrode pattern by brazing-bonding.

The spacer may be made of a CPC material in which copper (Cu), copper-molybdenum (Cu—Mo), and copper (Cu) are sequentially stacked.

The electrode pattern may be made of a copper (Cu) material, and formed on at least one surface of a metal layer brazing-bonded to both surfaces of the ceramic base material.

A power module according to this embodiment may include a pair of ceramic substrates in which an electrode pattern is formed on at least one surface of a ceramic base material, a semiconductor chip disposed between the pair of ceramic substrates, and electrically connected to the electrode pattern, and a spacer disposed between the pair of ceramic substrates, having electrical conductivity and thermal conductivity, and made of a CPC material in which copper (Cu), copper-molybdenum (Cu—Mo), and copper (Cu) are sequentially stacked, which is a material having a lower coefficient of thermal expansion than that of the electrode pattern.

The spacer may be provided to have an area corresponding to an area of the semiconductor chip.

The spacer may also be brazing-bonded to all of one surface or both surfaces of the semiconductor chip, and brazing-bonded to the ceramic baser material or the electrode pattern.

### Advantageous Effects of Invention

According to the present disclosure, the spacer made of CPC having the coefficient of thermal expansion lower than the coefficient of thermal expansion of the electrode pattern is used in the space between the pair of ceramic substrates or used by being interposed between the electrode pattern and the semiconductor chip. Accordingly, even when the temperature of the power module due to the heat generated from the semiconductor chip increases, the distance between the pair of ceramic substrates may be constantly maintained, so that the semiconductor chip are not separated from the electrode pattern, and the heat of the semiconductor chip can be effectively transferred to the ceramic substrate, thereby improving the heat-dissipation performance of the power module.

### BRIEF DESCRIPTION OF DRAWINGS

FIG. 1 is a perspective view showing a ceramic substrate for a power module according to an embodiment of the present disclosure.

FIG. 2 is a perspective view showing a state in which a spacer and an electrode pattern are separated in FIG. 1.

FIG. 3 is a partial cross-sectional view showing a power module according to an embodiment of the present disclosure.

FIG. 4 is a partial cross-sectional view showing a power module according to another embodiment of the present disclosure.

FIG. 5 is a flowchart showing a method of manufacturing the ceramic substrate for the power module according to an embodiment of the present disclosure.

FIG. 6 is a flowchart showing an operation of forming the spacer by a photolithography process in the method of manufacturing the ceramic substrate for the power module according to an embodiment of the present disclosure.

FIG. 7A is a schematic view showing a state in which a photoresist has been applied to the electrode pattern.

FIG. 7B is a schematic view showing a state in which a mask is disposed on the photoresist and then light is irradiated.

FIG. 7C is a schematic view showing a state in which an exposed photoresist has been developed.

FIG. 7D is a schematic view showing a state in which a portion other than a region where the photoresist remains has been partially etched in a thickness direction.

FIG. 7E is a schematic view showing a state in which the remaining photoresist has been removed.

### DESCRIPTION OF EMBODIMENTS

Hereinafter, embodiments of the present disclosure will be described in detail with reference to the accompanying drawings.

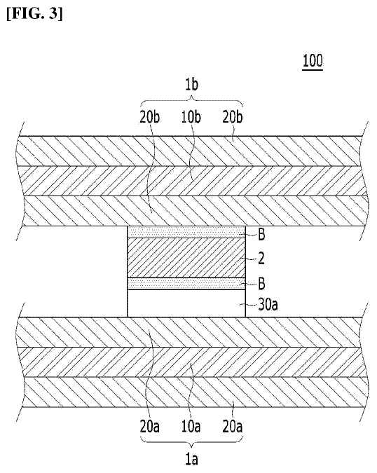

A ceramic substrate 1 for a power module according to an embodiment of the present disclosure may be applied to a double side cooling power module (reference numeral 100 in FIG. 3) in which a semiconductor chip formed of a diode, an insulated gate bipolar transistor (IGBT), a metal oxide semiconductor field effect transistor (MOSFET), a junction field effect transistor (JFET), or a high electric mobility transistor (HEMT), or made of a material such as a silicon carbide (SiC) or a gallium nitride (GaN) is mounted between two ceramic substrates. The power module is used to supply a high voltage current for driving a motor of hybrid electric vehicles and electric vehicles, and the double side cooling power module has excellent cooling performance compared to the single side cooling power module having a heat sink at one side, and thus may be applied to a high-output power module.

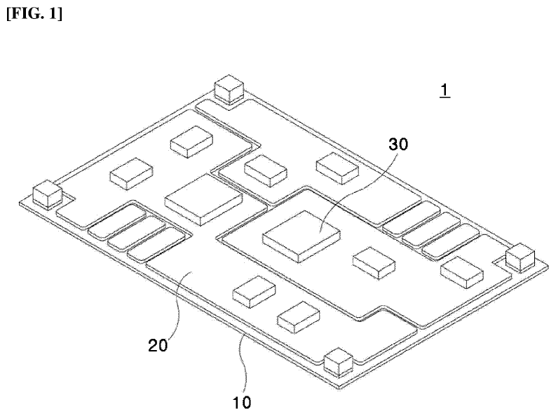

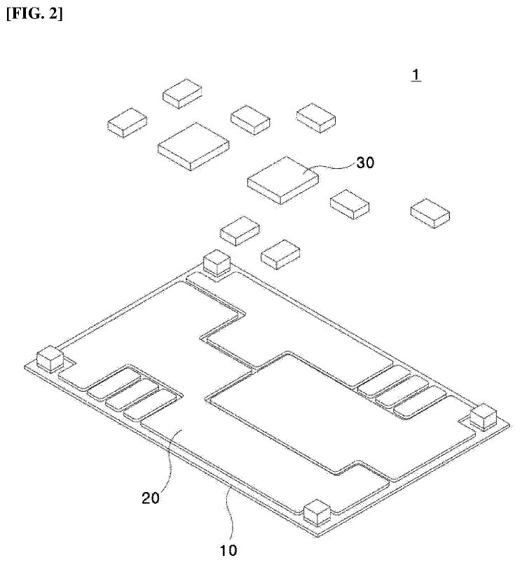

FIG. 1 is a perspective view showing a ceramic substrate for a power module according to an embodiment of the present disclosure, and FIG. 2 is a perspective view showing a state in which a spacer and an electrode pattern are separated in FIG. 1.

As shown in FIG. 1, the ceramic substrate 1 for the power module according to an embodiment of the present disclosure may include a ceramic base material 10, at least one electrode pattern 20 formed on the ceramic base material 10, and a spacer 30 disposed on the ceramic base material 10 or the electrode pattern 20, having electrical conductivity and thermal conductivity, and made of a material having a lower coefficient of thermal expansion than that of the electrode pattern 20.

For example, the ceramic base material 10 may be made of any one of alumina (Al₂O₃), AlN, SiN, and Si₃N₄, and may be sintered at a high temperature of 1000° C. or higher.

The electrode pattern 20 may be formed on the sintered ceramic base material 10. The electrode pattern 20 may be variously formed, and usually, may also be formed by brazing-bonding and then etching a metal layer made of a metallic material to the ceramic base material 10, or may also be formed by first patterning a metal plate through punch or mechanical processing and then brazing-bonding the patterned metal plate to the ceramic base material 10. A semiconductor chip 2 (see FIG. 3) may be mounted on the surface of the electrode pattern 20 formed as described above. The metal layer or metal plate forming the electrode pattern 20 may be made of a copper (Cu) material having excellent electrical conductivity and thermal conductivity. Accordingly, the electrode pattern 20 may be electrically connected to the semiconductor chip 2 to function to transfer a control signal, and function to quickly move heat generated from the semiconductor chip 2 toward a heat sink (not shown) coupled to the metal layer or the metal plate having volumes corresponding to the ceramic base material 10 and the electrode pattern 20.

The spacer 30 may be installed on the ceramic base material 10 or the electrode pattern 20. The spacer 30 may also have both ends bonded to the ceramic substrates 10 facing each other to be used as a support structure, and may also be installed on a region where the semiconductor chip 2 of the electrode pattern 20 is mounted or the electrode pattern 20 on which the semiconductor chip 2 is not mounted.

The spacer 30 may be a CPC material in which Cu/Cu—Mo/Cu are sequentially stacked. The coefficient of thermal expansion (CTE) of the CPC material is 6.8 to 7.8 ppm/K, and the thermal conductivity is 220 to 280 W/m·K. As described above, the CPC material has a relatively higher thermal conductivity than the polymer-based thermal interface material, so that it may be advantageous for heat dissipation, and has a relatively lower coefficient of thermal expansion than that of copper used as the material of the electrode pattern 20, so that it is possible to minimize deformation of the spacer 30.

As described above, when the spacer 30 is used as the support structure for maintaining the distance between the ceramic substrates 1, the spacer 30 has a relatively lower coefficient of thermal expansion than that of the electrode pattern 20, so that it is possible to minimize damage to the power module that occurs due to thermal expansion caused by heat generated from the semiconductor chip 2.

In addition, when the spacer 30 is used by being interposed between the semiconductor chip 2 and the electrode pattern 20, which are mounted between a pair of ceramic substrates 1, the spacer 30 has good thermal conductivity of about 220 to 280 W/m·K, so that it is possible to quickly transfer heat emitted from the semiconductor chip 2 to the ceramic base material 10, thereby improving the heat-dissipation performance. At this time, the spacer 30 may be formed to correspond to an area of the semiconductor chip 2 mounted on the electrode pattern 20. When the area of the spacer 30 is formed to be smaller than that of the semiconductor chip 2, it is difficult to expect effective heat dissipation, and when the area of the spacer 30 is formed to be much larger than the area of the semiconductor chip 2, there may occur a problem in that the spacer 30 interferes with other surrounding parts to cause an electrical short-circuit, so that the spacer 30 may be formed to be slightly larger than or equal to the area corresponding to the semiconductor chip 2. The spacer 30 may be brazing-bonded to the region of the electrode pattern 20 on which the semiconductor chip 2 is mounted. The brazing process is a method of bonding the spacer 30 and the electrode pattern 20 at the operating temperature of about 400 to 900° C. with the filler layer interposed between the spacer 30 and the electrode pattern 20. At this time, the filler layer may have a structure in which one selected from Ag, Cu, and AgCu or two or more among them are mixed. Ag, Cu, and AgCu alloys have high thermal conductivity, so that it is possible to quickly transfer heat generated from the semiconductor chip 2 to the spacer 30. The brazing process is a process of bonding the two base materials by applying heat at which the base material is not damaged, so that it is possible to couple the spacer 30 on which the semiconductor chip 2 is mounted and the electrode pattern 20 while minimizing damage to the space 30 and the electrode pattern 20.

As described above, when the electrode pattern 20 and the semiconductor chip 2 are bonded thermally and electrically using the spacer 30, the spacer 30 has a higher coefficient of thermal expansion than that of the thermal interface material (TIM) made of a mixture of polymer and ceramic filler, but has a lower coefficient of thermal expansion than that of the metal widely used as an electrode material such as copper, so that it is possible to secure dimension stability of the power module even when the spacer 30 is used in a high temperature environment for a long time.

Hereinafter, the power module 100 according to an embodiment of the present disclosure will be described in detail. The sizes of the respective components in the drawings describing the power module 100 may be exaggerated for description, and do not mean a size that is actually applied.

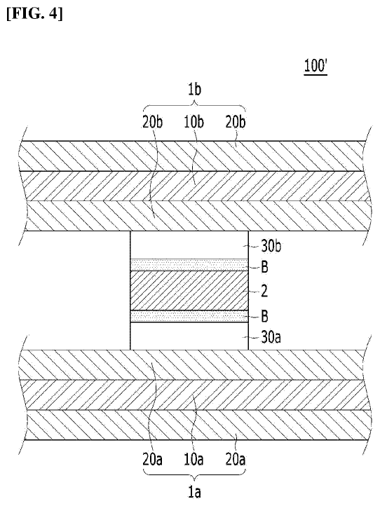

FIG. 3 is a partial cross-sectional view showing a power module according to an embodiment of the present disclosure, and FIG. 4 is a partial cross-sectional view showing a power module according to another embodiment of the present disclosure.

As shown in FIGS. 3 and 4, the power module 100 according to the present disclosure as the double side cooling power module may include a pair of ceramic substrates 1a and 1b in which electrode patterns 20a and 20b are formed on at least one surfaces of ceramic base materials 10a and 10b, the semiconductor chip 2 disposed between the pair of ceramic substrates 1a and 1b, and electrically connected to the electrode patterns 20a and 20b, and the spacer 30 disposed between the pair of ceramic substrates 1a and 1b, having electrical conductivity and thermal conductivity, and made of a material having a lower coefficient of thermal expansion than those of the electrode patterns 20a and 20b.

Here, at least one of the pair of ceramic substrates 1a and 1b may include the spacer 30 formed in a region where the semiconductor chip 2 is mounted on the electrode pattern 20. The spacer 30 may be made of a CPC material having high thermal conductivity and a low coefficient of thermal expansion to stably dissipate heat emitted from the semiconductor chip 2. As described above, the power module according to the present disclosure may mount the semiconductor chip 2 more precisely, and effectively dissipate heat of the semiconductor chip 2 by forming the spacer 30 in the mounting region where the semiconductor chip 2 such as an IGBT, a diode, a GaN chip, and a SiC chip is mounted.

FIG. 3 shows an example in which the power module 100 according to an embodiment of the present disclosure includes first and second ceramic substrates 1a and 1b in which the electrode patterns 20a and 20b are formed on the ceramic base materials 10a and 10b, and a first spacer 30a is provided on a first ceramic substrate 1a. Here, one surface of the semiconductor chip 2 may be bonded to an upper surface of the spacer 30 by a bonding layer B, and the other surface of the semiconductor chip 2 may be bonded to an electrode pattern 20b of a second ceramic substrate 1b by the bonding layer B. In addition, the spacer 30 may also be brazing-bonded to at least one of the ceramic base materials 10a and 10b of the first and second ceramic substrates 1a and 1b by the bonding layer B.

The bonding layer B may include solder or silver paste. The solder may be formed of a SnPb-based, SnAg-based, SnAgCu-based, or Cu-based solder paste having high bonding strength and excellent high-temperature reliability. The silver paste has better high-temperature reliability and higher thermal conductivity than those of the solder. Silver paste may contain 90 to 99 wt % of Ag powder and 1 to 10 wt % of a binder to have high thermal conductivity, and Ag powder may be nanoparticles. Ag powder of nanoparticles has high bonding density and high thermal conductivity due to a high surface area.

As shown in FIG. 4, a power module 100′ according to another embodiment of the present disclosure may have a first spacer 30a and a second spacer 30b formed on the first and second ceramic substrates 1a and 1b, respectively, and both surfaces of the semiconductor chip 2 may be bonded to the first spacer 30a and the second spacer 30b. At this time, both surfaces of the semiconductor chip 2 may be bonded to the first and second spacers 30a and 30b by the bonding layer B including solder or silver paste. As described above, when both surfaces of the semiconductor chip 2 are bonded to the first and second spacers 30a and 30b, heat dissipation performance may be further improved.

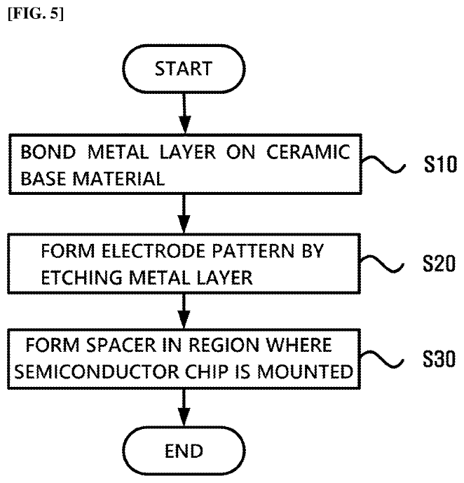

Hereinafter, a method of manufacturing the ceramic substrate 1 for the power module according to an embodiment of the present disclosure will be described with reference to FIG. 5.

FIG. 5 is a flowchart showing a method of manufacturing the ceramic substrate for the power module according to an embodiment of the present disclosure.

As shown in FIG. 5, the method of manufacturing the ceramic substrate for the power module according to an embodiment of the present disclosure may include an operation of bonding the metal layer on the ceramic base material 10 (S10), an operation of forming the electrode pattern 20 by etching the metal layer (S20), and an operation of forming the spacer 30 in the region of the electrode pattern 20 where the semiconductor chip is mounted (S30).

The bonding of the metal layer (S10) may bond the metal layer made of a metal on the ceramic base material 10 by an active metal brazing (AMB) process. The ceramic base material 10 may be, for example, any one of alumina (Al₂O₃), AlN, SiN, and Si₃N₄. The metal layer made of metal may be fired at 780 to 1100° C. to be brazing-bonded to the upper and lower surfaces of the ceramic base material 10. The substrate is called an active metal brazing (AMB) substrate.

Here, the metal layer may be a copper material. Since copper has a thermal conductivity of 400 W/m·K, heat generated from the semiconductor chip 2 and transferred through the spacer 30 may be effectively dissipated.

The operation of forming the electrode pattern (S20) may form the electrode pattern 20 by etching the metal layer bonded to the ceramic base material 10 according to a designed pattern.

The operation of forming the spacer (S30) may brazing-bond the spacer 30 to the region of the electrode pattern 20 where the semiconductor chip is mounted. The brazing is a method of bonding the spacer 30 and the electrode pattern 20 at the operating temperature of about 400 to 900° C. with the filler layer interposed between the spacer 30 and the electrode pattern 20. At this time, the filler layer may have a structure in which one selected from Ag, Cu, and AgCu or two or more among them are mixed. Ag, Cu and AgCu alloys have high thermal conductivity to facilitate the dissipation of heat generated from the semiconductor chip.

The spacer 30 may be a CPC material in which Cu/Cu—Mo/Cu are sequentially stacked. The coefficient of thermal expansion (CTE) of the CPC material is 6.8 to 7.8 ppm/K, and the thermal conductivity is 220 to 280 W/m·K. As described above, the CPC material has a relatively higher thermal conductivity than the polymer-based thermal interface material, so that it may be advantageous for heat dissipation, and has a relatively lower coefficient of thermal expansion than that of copper used as the material of the electrode pattern 20, so that it is possible to minimize deformation of the spacer 30.

As described above, the method of manufacturing the ceramic substrate for the power module according to an embodiment of the present disclosure may increase precision upon mounting the semiconductor chip, and minimize damage to the power module that occurs due to the thermal expansion caused by heat generated from the semiconductor chip 2 by attaching the spacer 30 to the position where the semiconductor chip is to be mounted.

Meanwhile, the operation of forming the spacer (S30) may also form the spacer 30 by partially etching the electrode pattern 20 in the thickness direction by a photolithography process.

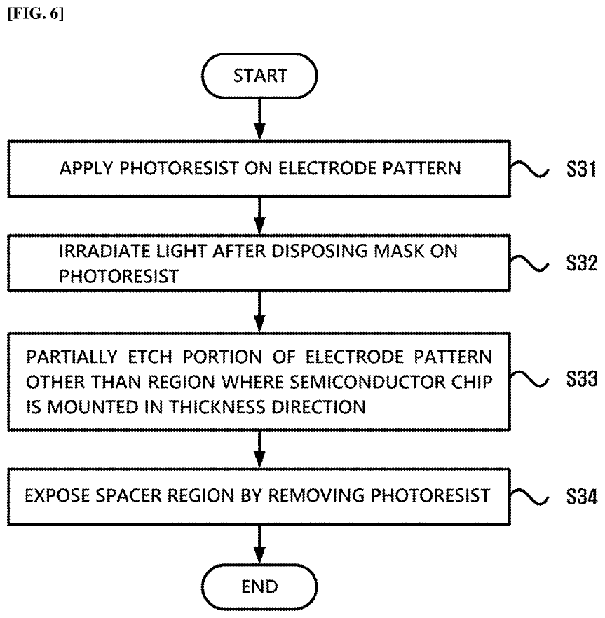

As shown in FIG. 6, the operation of forming the spacer 30 (S30) may include an operation of applying a photoresist P on the electrode pattern 20 (S31), an operation of irradiating light after disposing a mask M having a pattern corresponding to the region where the semiconductor chip is mounted on the photoresist P (S32), an operation of partially etching a portion of the electrode pattern 20 other than the region in the thickness direction after developing the exposed photoresist P (S33), and an operation of exposing the spacer 30 region by removing the photoresist P remaining on the region (S34).

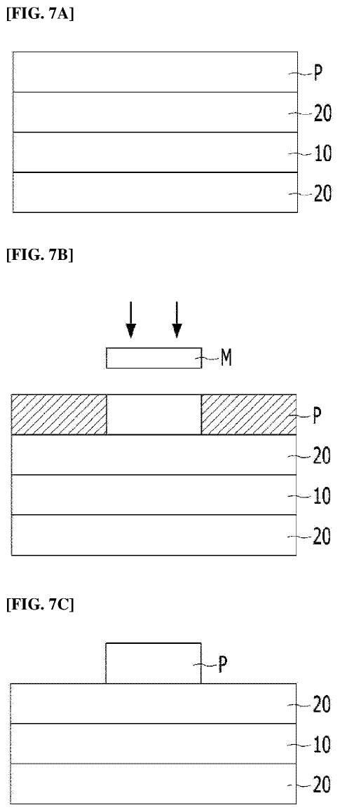

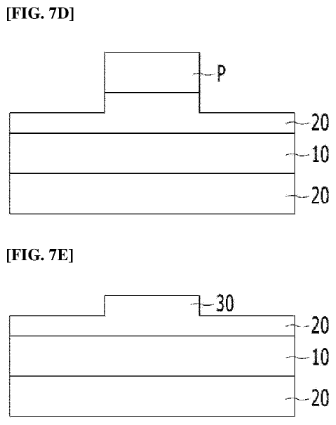

In the operation of applying the photoresist P (S31), the photoresist P may be applied to the electrode pattern 20 at a certain thickness as shown in FIG. 7A. The electrode pattern 20 may be made of copper. In addition, it is preferable that the electrode pattern 20 is formed to have a thickness larger than a designed thickness. For example, the thickness of the ceramic base material 10 may be 0.32 t, and may be formed to a thickness of 1.0 t, which is larger than 0.5 t, which is the thickness of the designed electrode pattern 20. Here, the thickness of 0.5 t added is to form the spacer 30.

As shown in FIG. 7B, the operation of irradiating light (S32) may dispose the mask M having the pattern corresponding to the region on which the semiconductor chip is mounted on the photoresist P and then irradiate a light source such as ultra violet (UV). As described above, the pattern formed on the mask M may be transferred to the photoresist P by irradiating the light source through the mask M. Here, a type in which only a portion exposed by the light source is developed is a positive method, and a type in which only an unexposed portion is developed is a negative method. Although the present disclosure describes an example in which a positive type photoresist is used, a negative type photoresist may also be used.

In the etching operation (S33), when the photoresist P is developed after exposure, only the photoresist P in the region corresponding to the mask M pattern remains as shown in FIG. 7C.

Thereafter, when the portion without the photoresist P, that is, the portion other than the region where the semiconductor chip is mounted, is partially etched in the thickness direction by a process such as dry etching or wet etching, as shown in FIG. 7D, the portion where the photoresist P remains, that is, the spacer 30 region may protrude.

In other words, when the electrode pattern 20 is formed to a thickness of 1.0 t added by 0.5 t than the designed thickness, the portion where the photoresist P remains may protrude more than the etched portion by 0.5 t in thickness by half-etching the portion without the photoresist P by the thickness of 0.5 t.

As shown in FIG. 7E, the operation of exposing the spacer region (S34) may expose the spacer 30 region, which is the region where the semiconductor chip is mounted by removing the photoresist P remaining on the spacer 30 region.

As described above, the method of manufacturing the ceramic substrate for the power module according to another embodiment of the present disclosure may integrally form the spacer 30 in the region where the semiconductor chip is mounted by partially etching the electrode pattern 20 in the thickness direction by the photolithography process. As the spacer 30 is formed, it is possible to improve precision when the semiconductor chip is mounted, and improve heat dissipation performance.

The present disclosure has been described above with reference to the exemplary drawings, but is not limited by the described embodiments, and it is apparent to those skilled in the art that the present disclosure may be variously modified and changed without departing from the spirit and scope of the present disclosure. Accordingly, these modified examples or changed examples will belong to the claims of the present disclosure, and the scope of the present disclosure should be construed based on the appended claims.

1. A ceramic substrate for a power module comprising:
a ceramic base material;
at least one electrode pattern formed on the ceramic base material; and
at least one spacer disposed on the ceramic base material or the electrode pattern,
wherein the spacer has electrical conductivity and thermal conductivity, and is made of a material having a lower coefficient of thermal expansion than that of the electrode pattern.

2. The ceramic substrate for the power module of claim 1,
wherein the spacer is bonded to a semiconductor chip mounted on the electrode pattern.

3. The ceramic substrate for the power module of claim 1,
wherein the spacer is brazing-bonded to the electrode pattern.

4. The ceramic substrate for the power module of claim 1,
wherein the spacer is made of a CPC material in which copper (Cu), copper-molybdenum (Cu—Mo), and copper (Cu) are sequentially stacked.

5. The ceramic substrate for the power module of claim 1,
wherein the electrode pattern is formed on at least one surface of a metal layer brazing-bonded to both surfaces of the ceramic base material.

6. The ceramic substrate for the power module of claim 5,
wherein the metal layer is copper (Cu).

7. A power module comprising:
a pair of ceramic substrates in which an electrode pattern is formed on at least one surface of a ceramic base material;
a semiconductor chip disposed between the pair of ceramic substrates, and electrically connected to the electrode pattern; and
a spacer disposed between the pair of ceramic substrates, having electrical conductivity and thermal conductivity, and made of a material having a lower coefficient of thermal expansion than that of the electrode pattern.

8. The power module of claim 7,
wherein the spacer is bonded to one surface of the semiconductor chip.

9. The power module of claim 7,
wherein the spacer is bonded to both surfaces of the semiconductor chip.

10. The power module of claim 7,
wherein the spacer has an area corresponding to an area of the semiconductor chip.

11. The power module of claim 7,
wherein the spacer is brazing-bonded to the ceramic base material.

12. The power module of claim 7,
wherein the spacer is brazing-bonded to the electrode pattern.

13. The power module of claim 7,
wherein the spacer is made of a CPC material in which copper (Cu), copper-molybdenum (Cu—Mo), and copper (Cu) are sequentially stacked.
